(19) United States
(12) Patent Application Publication
(10) Pub. No.: US 2024/0071691 A1
(43) Pub. Date: Feb. 29, 2024

(54) SEMICONDUCTOR DEVICE

(71) Applicant: Murata Manufacturing Co., Ltd., Nagaokakyo-shi (JP)

(72) Inventors: Takeshi KAGAWA, Nagaokakyo-shi (JP); Masaki TSUKIDA, Nagaokakyo-shi (JP)

(21) Appl. No.: 18/502,440

(22) Filed: Nov. 6, 2023

Related U.S. Application Data
(63) Continuation of application No. PCT/JP2022/019613, filed on May 9, 2022.

(30) Foreign Application Priority Data
May 10, 2021 (JP) 2021-079846

(51) Int. Cl. H01G 4/33; H01G 4/224; H01G 4/30

(52) U.S. Cl. CPC H01G 4/33; H01G 4/224; H01G 4/306

(57) ABSTRACT

A capacitor that includes: a substrate having a first principal surface and a second principal surface opposed to each other in a thickness direction, wherein the first principal surfaces includes a step in a plan view from the thickness direction; an insulating film on the first principal surface of the substrate; a first electrode layer on the insulating film and positioned within a boundary defined by the step in the plan view; a dielectric film on the first electrode layer; a second electrode layer on the dielectric film; a moisture-resistant film on the dielectric film and the second electrode layer; a protective layer on the moisture-resistant film; and an outer electrode penetrating through the protective layer.

### CROSS REFERENCE TO RELATED APPLICATIONS

The present application is a continuation of International application No. PCT/JP2022/019613, filed May 9, 2022, which claims priority to Japanese Patent Application No. 2021-079846, filed May 10, 2021, the entire contents of each of which are incorporated herein by reference.

### TECHNICAL FIELD

The present invention relates to semiconductor devices.

### BACKGROUND ART

As a typical capacitor element for use in a semiconductor integrated circuit, for example, a metal insulator metal (MIM) capacitor has been known. The MIM capacitor has a structure of a parallel plate type with an insulator interposed between a lower electrode and an upper electrode.

Patent Document 1 discloses a thin film capacitor formed on a support substrate and having: a capacitor portion having a first capacitor electrode, a capacitor dielectric film formed on the first capacitor electrode, and a second capacitor electrode formed on the capacitor dielectric film; an extended electrode extended from the first capacitor electrode or the second capacitor electrode and formed of a conductive barrier film for preventing diffusion of hydrogen or moisture; and an electrode for external connection connected to the extended electrode.
Patent Document 1: Japanese Unexamined Patent Application Publication No. 2007-173386

### SUMMARY OF THE INVENTION

In the conventional semiconductor device such as the capacitor described in Patent Document 1, films such as the dielectric film are formed onto an end portion of the element. Since these films are cut at the time of dicing, film chipping tends to occur, and film peeling tends to occur at the end portion of the element. Thus, with moisture entering from an interface between the films into the element, the lower electrode and the upper electrode, which are inner electrodes, tend to be corroded.

The present invention provides ways to solve the above-described problem, and has an object of providing a highly moisture-resistant semiconductor device.

A semiconductor device according to a preferred embodiment of the present invention includes: a substrate having a first principal surface and a second principal surface opposed to each other in a thickness direction; an insulating film on the first principal surface of the substrate; a first electrode layer on the insulating film; a dielectric film on the first electrode layer; a second electrode layer on the dielectric film; a moisture-resistant film on the dielectric film and the second electrode layer; a protective layer on the moisture-resistant film; and an outer electrode penetrating through the protective layer.

In a first aspect, the first principal surface of the substrate includes a step in a plan view from the thickness direction, and the first electrode layer on the insulating film is positioned within a boundary defined by the step in the plan view.

In a second aspect, the first principal surface of the substrate includes a groove in a plan view from the thickness direction, and the first electrode layer on the insulating film is positioned within a boundary defined by the grove in the plan view.

According to aspects of the present invention, a highly moisture-resistant semiconductor device can be provided.

### BRIEF DESCRIPTION OF THE DRAWINGS

FIG. 1 is a sectional view schematically depicting one example of a capacitor according to a first embodiment of the present invention.

FIG. 2 is a plan view schematically depicting one example of the capacitor according to the first embodiment of the present invention.

FIG. 3A is a sectional view schematically depicting one example of a process of preparing a substrate.

FIG. 3B is a sectional view schematically depicting one example of a process of forming a step in the substrate.

FIG. 3C is a sectional view schematically depicting one example of a process of forming an insulating film.

FIG. 3D is a sectional view schematically depicting one example of a process of forming a first electrode layer.

FIG. 3E is a sectional view schematically depicting one example of a process of forming a dielectric film.

FIG. 3F is a sectional view schematically depicting one example of a process of forming a second electrode layer.

FIG. 3G is a sectional view schematically depicting one example of a process of forming a moisture-resistant film.

FIG. 3H is a sectional view schematically depicting one example of a process of forming an opening in the dielectric film and the moisture-resistant film.

FIG. 3I is a sectional view schematically depicting one example of a process of forming a protective layer.

FIG. 3J is a sectional view schematically depicting one example of a process of forming an outer electrode.

FIG. 4 is a sectional view schematically depicting one example of a capacitor according to a second embodiment of the present invention.

FIG. 5 is a sectional view schematically depicting one example of a capacitor according to a third embodiment of the present invention.

FIG. 6 is a sectional view schematically depicting one example of a capacitor according to a fourth embodiment of the present invention.

FIG. 7 is a sectional view schematically depicting one example of a capacitor according to a fifth embodiment of the present invention.

FIG. 8 is a sectional view schematically depicting one example of a capacitor according to a sixth embodiment of the present invention.

FIG. 9 is a plan view schematically depicting one example of the capacitor according to the sixth embodiment of the present invention.

FIG. 10 is a sectional view schematically depicting a modification of the capacitor depicted in FIG. 1.

FIG. 11 is a sectional view schematically depicting a modification of the capacitor depicted in FIG. 8.

### DETAILED DESCRIPTION OF THE PREFERRED EMBODIMENTS

A semiconductor device according to preferred embodiments of the present invention is described below.

However, the present invention is not limited to the following configurations and various aspects can be changed as appropriate without departing from the gist of the present invention. Note that one obtained by combining two or more of individual preferable configurations of the present invention described below is also the present invention.

It is to be understood that each embodiment described below is an example and partial replacement or combination of configurations described in different embodiments can be made. In a second embodiment onward, description about matters common to a first embodiment is omitted, and only different points are described. In particular, operations and effects similar to those by a similar configuration are not mentioned one by one for each embodiment.

In the following description, when each embodiment is not particularly distinguished, it is referred to simply as the “semiconductor device of the present invention”. The shapes, arrangements, and so forth of the semiconductor device of the present invention and the respective components are not limited to the examples depicted in the drawings.

Also in the following, as one embodiment of the semiconductor device of the present invention, a capacitor is described by way of example. The semiconductor device of the present invention may be a capacitor itself (that is, capacitor element) or a device including a capacitor.

### First Embodiment

In a first embodiment of the present invention, on an end portion of an element, a step is formed on a front surface of a substrate.

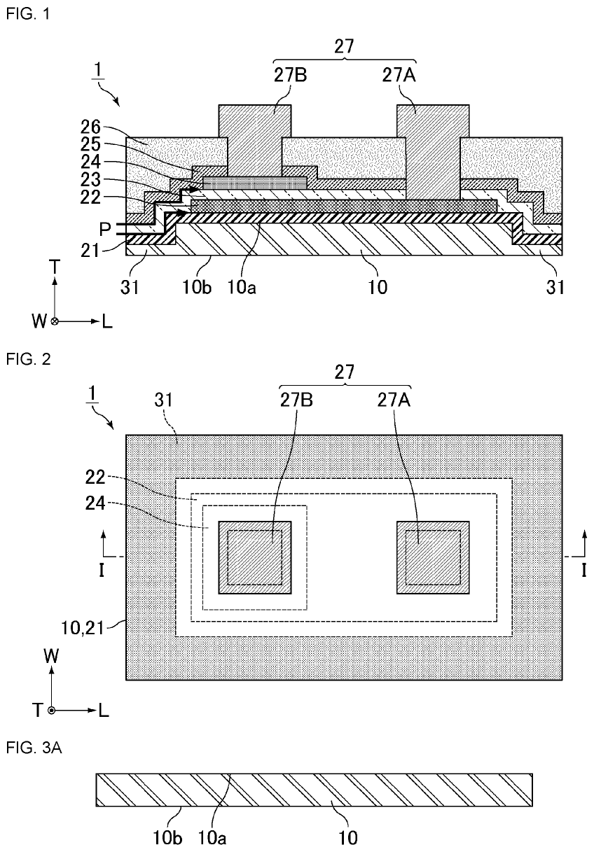

FIG. 1 is a sectional view schematically depicting one example of a capacitor according to the first embodiment of the present invention. FIG. 2 is a plan view schematically depicting one example of the capacitor according to the first embodiment of the present invention. FIG. 1 is a sectional view along an I-I line of the capacitor depicted in FIG. 2.

In the specification, a length direction, a width direction, and a thickness direction of the capacitor (semiconductor device) are taken as directions defined by an arrow L, an arrow W, and an arrow T, respectively, as depicted in FIG. 1, FIG. 2, and so forth. Here, the length direction L, the width direction W, and the thickness direction T are orthogonal to one another.

A capacitor 1 depicted in FIG. 1 and FIG. 2 includes a substrate 10 having a first principal surface 10a and a second principal surface 10b opposed to each other in the thickness direction (in FIG. 1 and FIG. 2, the direction indicated by the arrow T), an insulating film 21 provided on the first principal surface 10a of the substrate 10, a first electrode layer 22 provided on the insulating film 21, a dielectric film 23 provided on the first electrode layer 22, a second electrode layer 24 provided on the dielectric film 23, a moisture-resistant film 25 provided on the dielectric film 23 and the second electrode layer 24, a protective layer 26 provided on the moisture-resistant film 25, and an outer electrode 27 penetrating through the protective layer 26. The outer electrode 27 includes a first outer electrode 27A connected to the first electrode layer 22 and a second outer electrode 27B connected to the second electrode layer 24. The first outer electrode 27A penetrates through the protective layer 26, the moisture-resistant film 25, and the dielectric film 23, and the second outer electrode 27B penetrates through the protective layer 26 and the moisture-resistant film 25.

In the capacitor 1, the first electrode layer 22, the dielectric film 23, and the second electrode layer 24 are laminated in this order, configuring a MIM capacitor structure. By applying voltage between the first electrode layer 22 and the second electrode layer 24, it is possible to accumulate electric charges in the dielectric film 23.

As depicted in FIG. 1 and FIG. 2, on the first principal surface 10a of the substrate 10, a step 31 is formed on an outer side portion of the first electrode layer 22 in a plan view from the thickness direction T so that the first electrode layer 22 is positioned within a boundary defined by the step 31 in the plan view. At an end portion of the substrate 10 where the step 31 is formed, the thickness of the substrate 10 is small compared with a portion where the first electrode layer 22 is provided. In FIG. 1, the insulating film 21, the dielectric film 23, and the moisture-resistant film 25 are located so as to be along the step 31.

By forming the step 31 on the substrate 10, a moisture entering path (in FIG. 1, the moisture entering path is indicated by an arrow P) from a side wall of the element to the first electrode layer 22 or the second electrode layer 24 can be lengthened. As a result, moisture resistance of the capacitor 1 can be improved.

In the thickness direction T, when a difference in height of the first principal surface 10a of the substrate 10 (or a difference in thickness of the substrate 10) is defined as a “height of the step 31”, the height of the step 31 is not particularly limited but, for example, is 0.1% to 20% of the thickness of a portion of the substrate 10 where the first electrode layer 22 is positioned. The height of the step 31 is, for example, 0.1 μm to 10 μm.

In the length direction (in FIG. 1 and FIG. 2, the direction indicated by the arrow L) or the width direction (in FIG. 1 and FIG. 2, the direction indicated by the arrow W), when the dimension of the end portion of the substrate 10 where the step 31 is formed is defined as a “width of the step 31”, the length of the step 31 is not particularly limited but, for example, is 0.1% to 20% of the dimension of the substrate 10 in the length direction L, and the width of the step is 0.1% to 20% of the dimension of the substrate 10 in the width direction W. The width of the step 31 is, for example, 5 μm to 50 μm.

The step 31 may be continuously formed along the end portion of the substrate 10 as depicted in FIG. 2 or may be discontinuously formed. The height and width of the step 31 may be constant or inconstant.

The number of steps 31 is not particularly limited, and may be one as depicted in FIG. 1 and FIG. 2 or may be two or more. When there are two or more steps 31, the height and width of each step 31 may be equal or different.

The capacitor 1 depicted in FIG. 1 is manufactured with, for example, the following method.

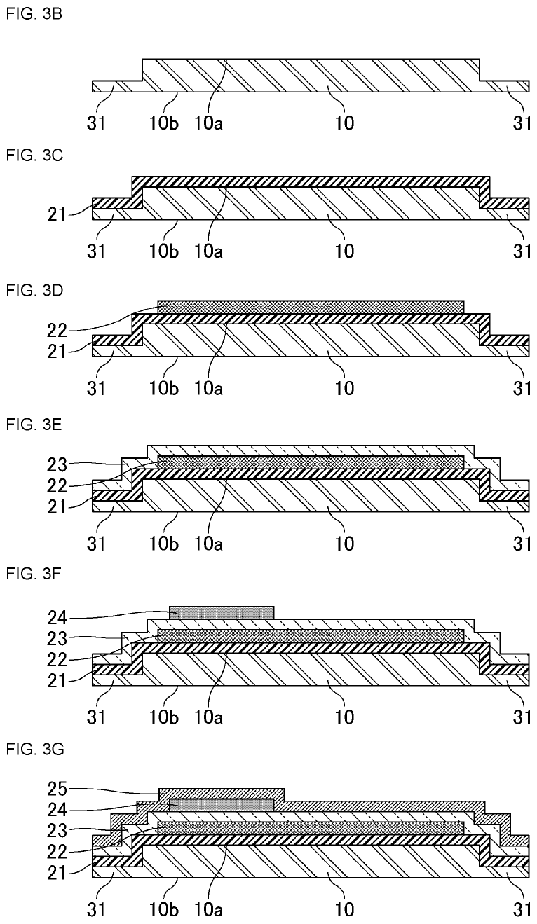

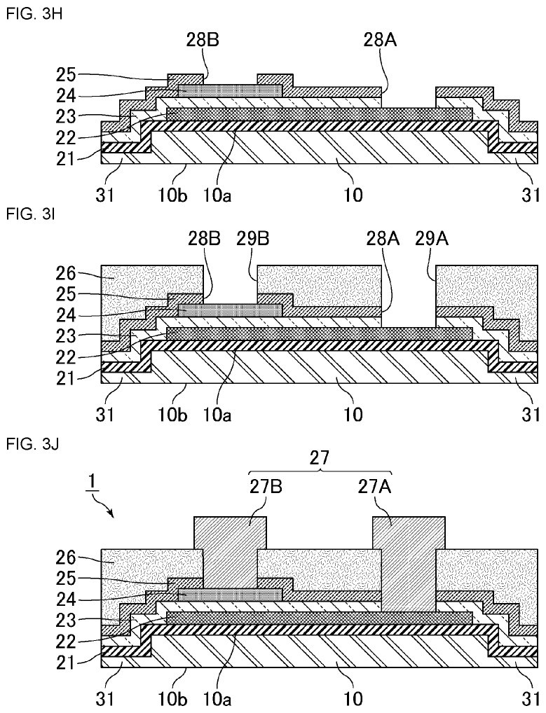

FIG. 3A to FIG. 3J are sectional views schematically depicting one example of a method of manufacturing the capacitor according to the first embodiment of the present invention. While attention is paid to one capacitor element in FIG. 3A to FIG. 3J, a plurality of capacitor elements may be simultaneously formed on the substrate. That is, a collective board having a plurality of capacitors may be manufactured and then separated into individual capacitor elements.

FIG. 3A is a sectional view schematically depicting one example of a process of preparing a substrate.

As depicted in FIG. 3A, the substrate 10 having the first principal surface 10a and the second principal surface 10b opposed to each other in the thickness direction is prepared.

The substrate 10 is not particularly limited, but is preferably a semiconductor device such as a silicon substrate or a gallium arsenide substrate, or an insulating substrate made of glass, alumina, or the like.

FIG. 3B is a sectional view schematically depicting one example of a process of forming a step in the substrate.

As depicted in FIG. 3B, the step 31 is formed on the first principal surface 10a of the substrate 10.

Formation of the step 31 can be performed with, for example, etching.

FIG. 3C is a sectional view schematically depicting one example of a process of forming an insulating film.

As depicted in FIG. 3C, the insulating film 21 is formed on the first principal surface 10a of the substrate 10 where the step 31 is formed.

In FIG. 3C, the insulating film 21 is formed so as to cover the entirety of the first principal surface 10a of the substrate 10.

Formation of the insulating film 21 can be performed with, for example, thermal oxidation, chemical vapor deposition (CVD), physical vapor deposition (PVD), or the like.

The material configuring the insulating film 21 is not particularly limited, but SiO₂, SiN, Al₂O₃, and so forth are preferably cited.

FIG. 3D is a sectional view schematically depicting one example of a process of forming a first electrode layer.

As depicted in FIG. 3D, the first electrode layer 22 is formed on the insulating film 21.

In FIG. 3D, the first electrode layer 22 is formed on the insulating film 21 in an inner side area of an area where the substrate 10 and the insulating film 21 occupy and an inner side area of the step 31. With the first electrode layer 22 not formed onto end portions of the substrate 10 and the insulating film 21, the first electrode layer 22 is prevented from being exposed to an end face of the capacitor 1 to cause a short circuit with another component or the like.

Formation of the first electrode layer 22 can be performed with, for example, liftoff, plating, etching, or the like. Alternatively, the pattern of the first electrode layer 22 can be formed by combining sputtering, photolithography, and etching together.

The material configuring the first electrode layer 22 is not particularly limited, but Cu, Ag, Au, Al, Pt, an alloy containing at least one type of these metals, and so forth are preferably cited.

FIG. 3E is a sectional view schematically depicting one example of a process of forming a dielectric film.

As depicted in FIG. 3E, the dielectric film 23 is formed on the first electrode layer 22.

In FIG. 3E, the dielectric film 23 is formed on the entire substrate 10 so as to cover the first electrode layer 22.

Formation of the dielectric film 23 can be performed with, for example, CVD, PVD, or the like.

The material configuring the dielectric film 23 is not particularly limited, but oxides or nitrides such as SiO₂, SiN, Al₂O₃, HfO₂, and Ta₂O₅ are preferably cited.

FIG. 3F is a sectional view schematically depicting one example of a process of forming a second electrode layer.

As depicted in FIG. 3F, the second electrode layer 24 is formed on the dielectric film 23.

In FIG. 3F, the second electrode layer 24 is formed on part of the dielectric film 23. The area where the second electrode layer 24 is formed serves as an electrostatic capacity forming portion, and functions as a capacitor.

As with formation of the first electrode layer 22, formation of the second electrode layer 24 can be performed with, for example, liftoff, plating, etching, or the like. Alternatively, the pattern of the second electrode layer 24 can be formed by combining sputtering, photolithography, and etching together.

The material configuring the second electrode layer 24 is not particularly limited, but Cu, Ag, Au, Al, Pt, an alloy containing at least one type of these metals, and so forth are preferably cited.

FIG. 3G is a sectional view schematically depicting one example of a process of forming a moisture-resistant film.

As depicted in FIG. 3G, the moisture-resistant film 25 is formed on the dielectric film 23 and the second electrode layer 24.

In FIG. 3G, the moisture-resistant film 25 is formed on the entire dielectric film 23 so as to cover the second electrode layer 24.

Formation of the moisture-resistant film 25 can be performed with, for example, CVD, PVD, or the like.

The material configuring the moisture-resistant film 25 is not particularly limited, but a moisture-resistant material such as SiO₂ or SiN is preferably cited.

FIG. 3H is a sectional view schematically depicting one example of a process of forming an opening in the dielectric film and the moisture-resistant film.

As depicted in FIG. 3H, an opening 28A for exposing the first electrode layer 22 is formed in the dielectric film 23 and the moisture-resistant film 25. Also, an opening 28B for exposing the second electrode layer 24 is formed in the moisture-resistant film 25.

Formation of the openings 28A and 28B can be performed with, for example, etching or the like.

FIG. 3I is a sectional view schematically depicting one example of a process of forming a protective layer.

As depicted in FIG. 3I, the protective layer 26 is formed on the moisture-resistant film 25.

In FIG. 3I, the protective layer 26 has an opening 29A above the opening 28A and an opening 29B above the opening 28B.

Formation of the protective layer 26 can be performed with, for example, spin coating or the like. Also, the pattern of the protective layer 26 can be formed with photolithography, etching, or the like.

The material configuring the protective layer 26 is not particularly limited, but resin materials such as polyimide resin and resin in solder resist are preferably cited.

FIG. 3J is a sectional view schematically depicting one example of a process of forming an outer electrode.

As depicted in FIG. 3J, the outer electrode 27 penetrating through the protective layer 26 is formed.

In FIG. 3J, the first outer electrode 27A is formed so as to fill the opening 28A and the opening 29A, and the second outer electrode 27B is formed so as to fill the opening 28B and the opening 29B.

Formation of the outer electrode 27 can be performed with, for example, liftoff, plating, etching, or the like.

The material configuring the outer electrode 27 is not particularly limited, but Cu, Ni, Ag, Au, Al, or the like is preferably cited. The outer electrode 27 may have a single-layer structure or multi-layer structure. The outermost surface of the outer electrode 27 is preferably configured of

Au.

When a collective board having a plurality of capacitor elements is manufactured, this collective board is subjected to backgrinding, thereby being made thinner to have a desired element thickness. Then, with a method such as dicing, the collective board is separated into pieces each having a desired element size. That is, the collective board is cut into pieces each having an individual capacitor size.

The capacitor 1 depicted in FIG. 1 is manufactured in the above-described manner.

### Second Embodiment

In a second embodiment of the present invention, as a modification of the first embodiment, the insulating film, the dielectric film, and the moisture-resistant film are located on an inner side portion of the end portion of the element.

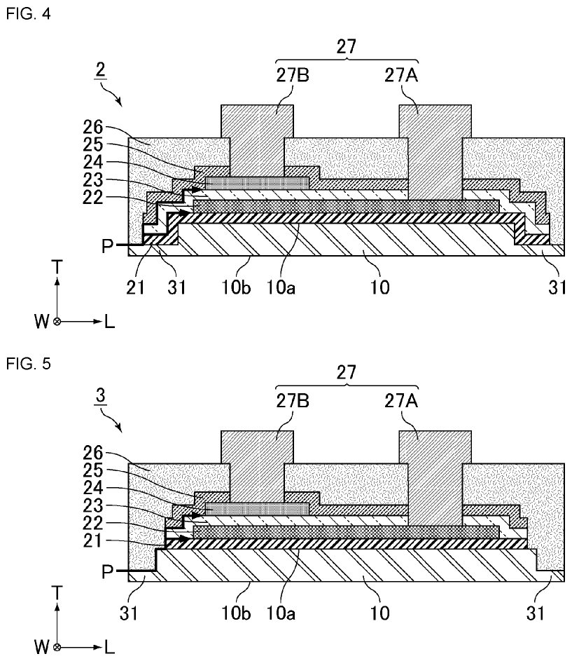

FIG. 4 is a sectional view schematically depicting one example of a capacitor according to the second embodiment of the present invention.

In a capacitor 2 depicted in FIG. 4, the insulating film 21, the dielectric film 23, and the moisture-resistant film 25 are located on an inner side portion of the end portion of the substrate 10.

In the structure of the second embodiment of the present invention, since it is not required to process the insulating film, the dielectric film, and the moisture-resistant film at the time of dicing or the like, chipping of these film does not occur. Furthermore, compared with the structure of the first embodiment, the moisture entering path to the first electrode layer or the second electrode layer can be lengthened. As a result, moisture resistance can be improved more than the first embodiment.

### Third Embodiment

In a third embodiment of the present invention, as a modification of the first embodiment, end portions of the insulating film, the dielectric film, and the moisture-resistant film are positioned within the boundary defined by the step in the plan view of the first principal surface of the substrate where the first electrode layer is positioned.

FIG. 5 is a sectional view schematically depicting one example of a capacitor according to the third embodiment of the present invention.

In a capacitor 3 depicted in FIG. 5, end portions of the insulating film 21, the dielectric film 23, and the moisture-resistant film 25 are positioned within the boundary defined by the step in the plan view of the first principal surface 10a of the substrate 10 where the first electrode layer 22 is positioned.

Also in the third embodiment of the present invention, effects similar to those of the second embodiment can be obtained.

### Fourth Embodiment

In a fourth embodiment of the present invention, as a modification of the second embodiment, an end portion of the insulating film is covered with the dielectric film, and an end portion of the dielectric film is covered with the moisture-resistant film.

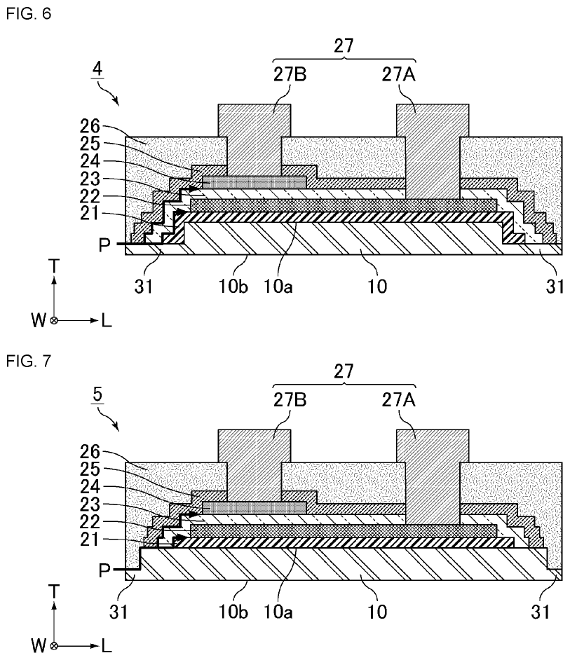

FIG. 6 is a sectional view schematically depicting one example of a capacitor according to the fourth embodiment of the present invention.

In a capacitor 4 depicted in FIG. 6, the insulating film 21, the dielectric film 23, and the moisture-resistant film 25 are provided on an inner side portion of the end portion of the substrate 10. Furthermore, an end portion of the insulating film 21 is covered with the dielectric film 23, and an end portion of the dielectric film 23 is covered with the moisture-resistant film 25.

In the fourth embodiment of the present invention, in addition to the effects described in the second embodiment, with the insulating film and the dielectric film sealed with the substrate and the moisture-resistant film, it is possible to ensure moisture resistance of the element without limiting the materials of the insulating film and the dielectric film in consideration of moisture resistance.

### Fifth Embodiment

In a fifth embodiment of the present invention, as a modification of the third embodiment, an end portion of the insulating film is covered with the dielectric film, and an end portion of the dielectric film is covered with the moisture-resistant film.

FIG. 7 is a sectional view schematically depicting one example of a capacitor according to the fifth embodiment of the present invention.

In a capacitor 5 depicted in FIG. 7, end portions of the insulating film 21, the dielectric film 23, and the moisture-resistant film 25 are positioned on a surface of the first principal surface 10a of the substrate 10 where the first electrode layer 22 is provided. Furthermore, the end portion of the insulating film 21 is covered with the dielectric film 23, and the end portion of the dielectric film 23 is covered with the moisture-resistant film 25.

Also in the fifth embodiment of the present invention, effects similar to those of the fourth embodiment can be obtained.

### Sixth Embodiment

In a sixth embodiment of the present invention, a groove is formed in a surface of the substrate in an inner side portion of an end portion of the element.

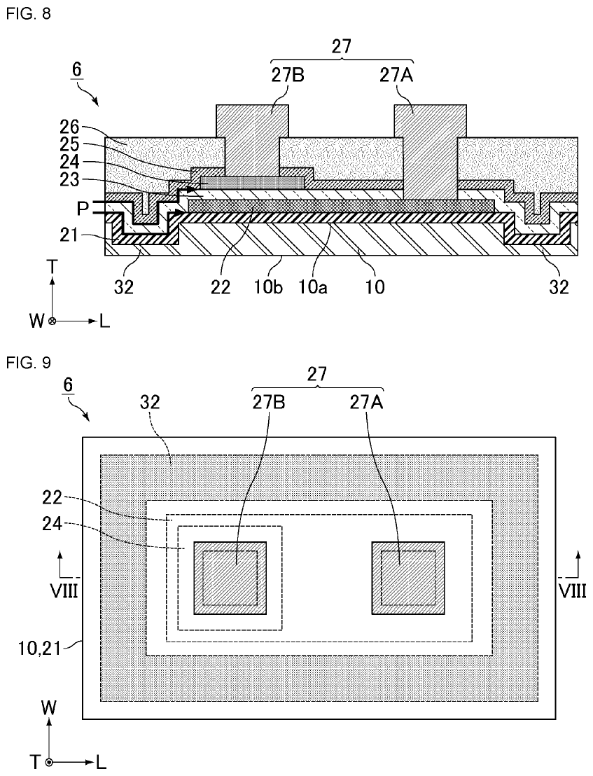

FIG. 8 is a sectional view schematically depicting one example of a capacitor according to the sixth embodiment of the present invention. FIG. 9 is a plan view schematically depicting one example of the capacitor according to the sixth embodiment of the present invention. FIG. 8 is a sectional view along a VIII-VIII line of the capacitor depicted in FIG. 9.

A capacitor 6 depicted in FIG. 8 and FIG. 9 includes, as with the capacitor 1 depicted in FIG. 1 and FIG. 2, the substrate 10 having the first principal surface 10a and the second principal surface 10b opposed to each other in the thickness direction (in FIG. 8 and FIG. 9, the direction indicated by the arrow T), the insulating film 21 provided on the first principal surface 10a of the substrate 10, the first electrode layer 22 provided on the insulating film 21, the dielectric film 23 provided on the first electrode layer 22, the second electrode layer 24 provided on the dielectric film 23, the moisture-resistant film 25 provided on the dielectric film 23 and the second electrode layer 24, the protective layer 26 provided on the moisture-resistant film 25, and the outer electrode 27 penetrating through the protective layer 26. The outer electrode 27 includes the first outer electrode 27A connected to the first electrode layer 22 and the second outer electrode 27B connected to the second electrode layer 24.

As depicted in FIG. 8 and FIG. 9, in the first principal surface 10a of the substrate 10, a groove 32 is formed in an outer side portion of the first electrode layer 22 in plan view from the thickness direction. In FIG. 8, the insulating film 21, the dielectric film 23, and the moisture-resistant film 25 are located so as to be along the groove 32.

By forming the groove 32 in the substrate 10, compared with a case in which the step 31 is formed on the substrate 10, the moisture entering path P to the first electrode layer 22 or the second electrode layer 24 can be lengthened. As a result, moisture resistance can be improved more than the capacitor 1.

In the thickness direction T, when a difference in height of the first principal surface 10a of the substrate 10 (or a difference in thickness of the substrate 10) is defined as a “depth of the groove 32”, the depth of the groove 32 is not particularly limited but, for example, is 0.1% to 20% of the thickness of a portion of the substrate 10 where the first electrode layer 22 is provided. The depth of the groove 32 is, for example, 0.1 μm to 10 μm.

In the length direction (in FIG. 8 and FIG. 9, the direction indicated by the arrow L) or the width direction (in FIG. 8 and FIG. 9, the direction indicated by the arrow W), when the dimension of the groove 32 is defined as a “width of the groove 32”, the width of the groove 32 is not particularly limited but, for example, is 0.1% to 20% of the dimension of the substrate 10 in the length direction L and is 0.1% to 20% of the dimension of the substrate 10 in the width direction W. The width of the groove 32 is, for example, 5 μm to 50 μm.

The groove 32 may be continuously formed along the end portion of the substrate 10 as depicted in FIG. 9 or may be discontinuously formed. The depth and width of the groove 32 may be constant or inconstant.

The number of grooves 32 is not particularly limited, and may be one as depicted in FIG. 8 and FIG. 9 or two or more may be formed side by side. When there are two or more grooves 32, the depth and width of each groove 32 may be equal or different.

The capacitor 6 depicted in FIG. 8 can be manufactured with a method similar to that of the capacitor 1 depicted in FIG. 1, except that the groove 32 is formed in place of the step 31.

### Other Embodiments

The semiconductor device of the present invention is not limited to the above-described embodiments and, as for the structure, manufacturing conditions, and so forth of the semiconductor device such as a capacitor, various applications and modifications can be made within the scope of the present invention.

For example, the semiconductor device of the present invention further may include a third electrode layer on the dielectric film away from the second electrode layer, and the first outer electrode may be connected to the third electrode layer.

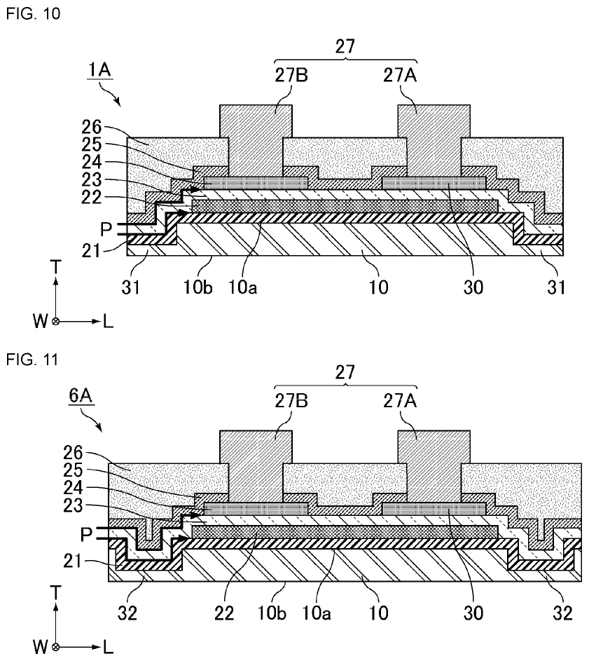

FIG. 10 is a sectional view schematically depicting a modification of the capacitor depicted in FIG. 1. FIG. 11 is a sectional view schematically depicting a modification of the capacitor depicted in FIG. 8.

Any of a capacitor 1A depicted in FIG. 10 and a capacitor 6A depicted in FIG. 11 includes the substrate 10 having the first principal surface 10a and the second principal surface 10b opposed to each other in the thickness direction (in FIG. 10 and FIG. 11, the direction indicated by the arrow T), the insulating film 21 provided on the first principal surface 10a of the substrate 10, the first electrode layer 22 provided on the insulating film 21, the dielectric film 23 provided on the first electrode layer 22, the second electrode layer 24 provided on the dielectric film 23, a third electrode layer 30 provided on the dielectric film 23 as separated from the second electrode layer 24, the moisture-resistant film 25 provided on the dielectric film 23, the second electrode layer 24, and the third electrode layer 30, the protective layer 26 provided on the moisture-resistant film 25, and the outer electrode 27 penetrating through the protective layer 26. The outer electrode 27 includes the first outer electrode 27A connected to the third electrode layer 30 and the second outer electrode 27B connected to the second electrode layer 24. The first outer electrode 27A penetrates through the protective layer 26 and the moisture-resistant film 25, and the second outer electrode 27B penetrates through the protective layer 26 and the moisture-resistant film 25.

In the structure as in the capacitor 1 depicted in FIG. 1 and the capacitor 6 depicted in FIG. 8 in which the first outer electrode is connected to the first electrode layer, the capacitor is formed on a left side. By contrast, in the structure as in the capacitor 1A depicted in FIG. 10 and the capacitor 6A depicted in FIG. 11 in which the first outer electrode is connected to the third electrode layer, capacitors are formed on left and right. In the structure of the capacitor including the third electrode layer, a portion where the first outer electrode is connected to the first electrode layer in the structure depicted in FIG. 1 is only replaced by structures provided sequentially with the first electrode layer, the dielectric film, and the third electrode layer. Thus, it is not required to take an additional element formation space for the structure depicted in FIG. 1. Therefore, a low-capacitance capacitor can be fabricated with the area of the same element being as it is. The structure as described above is effective when a dielectric film having a certain thickness or larger cannot be formed.

### REFERENCE SIGNS LIST

1, 1A, 2, 3, 4, 5, 6, 6A capacitor (semiconductor device)
10 substrate
10a first principal surface of the substrate
10b second principal surface of the substrate
21 insulating film
22 first electrode layer
23 dielectric film
24 second electrode layer
25 moisture-resistant film
26 protective layer
27 outer electrode
27A first outer electrode
27B second outer electrode
28A, 28B, 29A, 29B opening
30 third electrode layer
31 step
32 groove
P moisture entering path

1. A semiconductor device comprising:
a substrate having a first principal surface and a second principal surface opposed to each other in a thickness direction, wherein the first principal surfaces includes a step in a plan view from the thickness direction;
an insulating film on the first principal surface of the substrate;
a first electrode layer on the insulating film and positioned within a boundary defined by the step in the plan view;
a dielectric film on the first electrode layer;
a second electrode layer on the dielectric film;
a moisture-resistant film on the dielectric film and the second electrode layer;
a protective layer on the moisture-resistant film; and
an outer electrode penetrating through the protective layer.

2. The semiconductor device according to claim 1, wherein the insulating film, the dielectric film, and the moisture-resistant film are located on an inner side portion of an end portion of the substrate.

3. The semiconductor device according to claim 2, wherein a first thickness of the end portion of the substrate is smaller than a second thickness of a portion of the substrate where the first electrode layer is positioned.

4. The semiconductor device according to claim 2, wherein an end portion of the insulating film is covered with the dielectric film, and an end portion of the dielectric film is covered with the moisture-resistant film.

5. The semiconductor device according to claim 1, wherein the insulating film, the dielectric film, and the moisture-resistant film extend along the step.

6. The semiconductor device according to claim 1, wherein a height of the step is 0.1% to 20% of a thickness of a portion of the substrate where the first electrode layer is positioned.

7. The semiconductor device according to claim 6, wherein a width of the step is 0.1% to 20% of a width of the substrate, and length of the step is 0.1% to 20% of a length of the substrate.

8. The semiconductor device according to claim 1, wherein the step is continuous along an end portion of the substrate.

9. The semiconductor device according to claim 1, wherein end portions of the insulating film, the dielectric film, and the moisture-resistant film are positioned within the boundary defined by the step in the plan view.

10. The semiconductor device according to claim 9, wherein the end portion of the insulating film is covered with the dielectric film, and the end portion of the dielectric film is covered with the moisture-resistant film.

11. The semiconductor device according to claim 1, wherein an end portion of the insulating film is covered with the dielectric film, and an end portion of the dielectric film is covered with the moisture-resistant film.

12. The semiconductor device according to claim 1, wherein the outer electrode is a first outer electrode connected to the first electrode layer; and
the semiconductor device includes a second outer electrode penetrating the protecting layer and connected to the second electrode layer.

13. The semiconductor device according to claim 1, further comprising:
a third electrode layer on the dielectric film and spaced from the second electrode layer, wherein
the outer electrode is a first outer electrode connected to the third electrode layer, and
the semiconductor device includes a second outer electrode penetrating the protecting layer and connected to the second electrode layer.

14. A semiconductor device comprising:
a substrate having a first principal surface and a second principal surface opposed to each other in a thickness direction, wherein the first principal surfaces includes a groove in a plan view from the thickness direction;
an insulating film on the first principal surface of the substrate;
a first electrode layer on the insulating film and positioned within a boundary defined by the groove in the plan view;
a dielectric film on the first electrode layer;
a second electrode layer on the dielectric film;
a moisture-resistant film on the dielectric film and the second electrode layer;
a protective layer on the moisture-resistant film; and
an outer electrode penetrating through the protective layer.

15. The semiconductor device according to claim 14, wherein a depth of the groove is 0.1% to 20% of a thickness of a portion of the substrate where the first electrode layer is positioned.

16. The semiconductor device according to claim 15, wherein a width of the groove is 0.1% to 20% of a width of the substrate, and length of the groove is 0.1% to 20% of a length of the substrate.

17. The semiconductor device according to claim 14, wherein the groove is continuous along an end portion of the substrate.

18. The semiconductor device according to claim 14, wherein the outer electrode is a first outer electrode connected to the first electrode layer; and
the semiconductor device includes a second outer electrode penetrating the protecting layer and connected to the second electrode layer.

19. The semiconductor device according to claim 14, further comprising:
a third electrode layer on the dielectric film and spaced from the second electrode layer, wherein
the outer electrode is a first outer electrode connected to the third electrode layer, and
the semiconductor device includes a second outer electrode penetrating the protecting layer and connected to the second electrode layer.
